(19) United States
(12) Patent Application Publication
(10) Pub. No.: US 2024/0194814 A1
(43) Pub. Date: Jun. 13, 2024

(54) A diode radiation sensor

(71) Applicant: Fondazione Bruno Kessler, Povo (TN) (IT)

(72) Inventors: Alberto Gola, Trento (TN) (IT); Fabio Acerbi, Trento (IT) (IT); Giacomo Borghi, Trento (TN) (IT); Andrea Ficorella, Trento (TN) (IT); Alberto Mazzi, Trento (TN) (IT); Stefano Merzi, Trento (TN) (IT); Giovanni Paternoster, Trento (TN) (IT)

(21) Appl. No.: 18/555,483

(22) PCT Filed: Apr. 12, 2022
(86) PCT No.: PCT/IB2022/053405

§ 371 Date: Oct. 13, 2023

(30) Foreign Application Priority Data
Apr. 14, 2021 (IT) 102021000009434

(51) Int. Cl. H01L 31/107; G01T 1/24; H01L 31/18

(52) U.S. Cl. CPC H01L 31/107; G01T 1/248; H01L 31/1804

(57) ABSTRACT

A diode radiation sensor includes a substrate; a first layer of semiconductor material doped with a doping of a first type and provided on the front surface of the substrate; a second layer of semiconductor material doped with a doping of a second type of electrically opposite sign to the first type and provided at a first depth in the substrate, the first and the second layer forming a high electric field region therebetween; a third layer of semiconductor material doped with a doping of the second type and provided at a second depth in the substrate greater than the first depth; and a first isolation region provided peripherally to the substrate and extending deep in the substrate up to an intermediate area between the front and the rear surface of the substrate. A passivation layer is interposed between the lateral wall of the first isolation region and the substrate.

### DEFINITIONS

In the present patent, passivation layer in a device is meant as a layer of semiconductor material, however it is obtained, which is not emptied because it contains a sufficiently high concentration of majority carriers, during the normal operation of the device, of the same type as those present in the substrate on which the passivation layer is made.

### FIELD OF APPLICATION

The present invention can be applied to the field of radiation sensors and, in particular, to the field of diode radiation sensors.

More in detail, the present invention relates to a sensor having one or more charge multiplication diodes.

### BACKGROUND ART

Radiation sensors include single photon avalanche diodes (SPAD). A single SPAD consists of a charge multiplication diode which is polarized to work in geiger mode. A sensor can consist of a single SPAD or a set of SPADs, also called microcells or pixels. The sensors consisting of multiple SPADs include silicon photomultiplier sensors, also called SiPMs, which typically consist of SPADs connected in parallel.

Typically, as shown in FIG. 1, a microcell M is made in a substrate S of semiconductor material, typically epitaxial. In such a substrate S, a first layer P1 of doped semiconductor material is identified to be a first type of conductor (which can indifferently be of type n or type p, however of opposite sign to the doping of the substrate S). Such a first layer P1 is made on the front surface of the substrate S.

Then there is a second layer P2 of doped semiconductor material of opposite sign to the first layer P1 and made in depth in the substrate S. The latter is generally doped with the same sign as P2, but in smaller amounts. Then there is typically a doped bottom layer PF of the same sign of P2. The diode supply typically, but not necessarily, is between the first layer P1 and the bottom layer PF and, in accordance with the supply, between the first P1 and the second layer P2 or between the first P1 and the bottom layer PF an emptying region is created. In any case, between the first layer P1 and the second layer P2, in the presence of an appropriate polarization, a region with a high electric field E is created for generating the multiplier effect of the diode charge.

For each SPAD, at least one of the two poles or two electrical contacts must be functionally isolated from its neighbours in order to correctly operate as envisaged. For such a reason, a typically electrical and possibly also optical isolation region R is usually made therebetween. In fact, the optical isolation between adjacent cells is desirable, although not mandatory, for reducing related noise in terms of optical crosstalk.

However, this means that part of the volume of the device is dedicated to the isolation region R.

Furthermore, the second layer P2 must be spaced from such a region R in order to substantially obtain a guard ring which can be of the virtual guard ring type (VGR), i.e., in order to prevent excessively high electric fields at the edges of the active area.

Accordingly, in a SiPM, the sensitive area of each SPAD is significantly smaller than its total area due to the isolation region R and the guard ring VGR, forming the so-called dead edge of the cell. By defining the fill factor of the cell as the ratio of the sensitive area to the total area of a microcell, it is evident that the higher this number, the more efficient the single cell. Moreover, it is evident that the smaller the microcell, the more harmful a raised dead edge.

For what has been said thus far, therefore, the fill factor of a microcell is affected firstly by the space lost for the creation of the isolation region and secondly by the necessary spacing forming the virtual guard ring.

However, the isolation region also has further negative aspects for optical sensors of the SiPM or similar type.

Firstly, it affects the continuity of both the front and rear surfaces of the substrate. Since one of such two surfaces is used as the photon inlet surface, it is evident that the presence of such a region creates a physical discontinuity on such a surface.

Moreover, a discontinuity on the surfaces of the substrate creates an alteration of the topography of the surface with consequent problems in the supporting arrangement of further elements or in the substrate surface treatment.

### Presentation of the Invention

The object of the present invention is to at least partially overcome the drawbacks noted above, providing a radiation sensor having improved performance with respect to the equivalent sensors with regard to the ability of the incident photons to trigger with the greatest possible probability the effect of multiplying the charge of the diodes forming the sensor itself.

In particular, an object of the present invention is to provide a diode radiation sensor in which the fill factor of the microcells is improved with respect to the equivalent sensors of the prior art without significantly (or excessively) increasing the dark count rate.

More in detail, an object of the present invention is to provide a charge multiplication diode radiation sensor (typically avalanche diodes) in which the isolation regions have a lower incidence on the substrate decreasing, if not substantially cancelling, their contribution to the generation of the so-called dead edge.

Another object is to provide a diode radiation sensor in which the electric charges generated in the substrate are conveyed to the high electric field region and effectively trigger the charge multiplication effect.

A last but not least object is to provide a diode radiation sensor in which the isolation regions have a limited, if not null, effect on the incidence surface of the photons with respect to what occurs in the known optical sensors.

Such objects, as well as others which will become clearer below, are achieved by a diode radiation sensor in accordance with the following claims, which are to be considered as an integral part of the present disclosure.

In particular, it consists of one or more charge multiplication diodes which typically, but not necessarily, will be polarized to work in geiger mode. In such a sense, the sensor comprises a substrate made of semiconductor material and having two surfaces, a front surface and a rear surface opposite the front surface.

At least near the front surface there is at least a first layer of semiconductor material doped with a doping of a first type, whether of type n or of type p. Such a first layer is made so as to cover at least a first central area of the front surface of the substrate.

There is also at least a second layer of semiconductor material doped with a doping of a second type of electrically opposite sign to the first type. Such a second layer is made at a first depth in the substrate and extends substantially parallel to the first layer so as to affect a second area which identifies between the two layers, in the presence of an appropriate polarization of the sensor, a region with a high electric field. In other words, the two layers create the charge multiplication region of a diode of such a type whose working area, and therefore whose charge multiplication level, will be determined by the power supply of the same diode.

According to an aspect of the invention, the radiation sensor also comprises at least a third layer of semiconductor material doped with a doping of the second type and made at a second depth in the substrate which is greater than the first depth. In particular, the third layer affects a third area which, in plan projection, is lateral and at most overlapped on the second area.

From what has been said, it can be simplified by arguing that the third layer substantially forms a frame, although partially overlappable on the second layer, for the high electric field region and is positioned between it and the area of the substrate where the collection of charges occurs due to the incidence of the radiation. In this sense, advantageously, it prevents the charges generated in the substrate from heading towards the virtual guard ring, focusing them towards the high electric field region. In other words, it performs a substantially funnel function for the charges generated in the substrate which are thus directed towards the high electric field region. Advantageously, this is the case regardless of the extension of such a region.

With the execution just described, a relevant part of the voltage drop of the sensor is typically located between the first and second layer because it is the region with the highest electric field. Approximately, the same voltage drop is also identified between the first and third layer since the latter is typically at the same potential as the second layer. To avoid the multiplication of avalanches above the third layer, it is important that the voltage drop between the latter and the first layer is generated on a significantly longer path than that between the first and second layer. The execution of the third layer deeper than the second layer allows, advantageously, to increase the aforesaid path, limiting, if not cancelling, additional charge multiplications.

According to another aspect of the invention, the radiation sensor comprises at least a first isolation region made peripherally to the substrate and extending deep in the same substrate from the front surface to an intermediate area between it and the rear surface. In particular, such a first isolation region is laterally arranged at least on the first and the second layer. In the figures it is observed that the first isolation region goes far beyond, but this should not be considered limiting for the invention.

It follows that there is an electrical, and typically also optical, isolation between the surface layers of the charge multiplication diodes forming the sensor. However, advantageously, the portion of substrate not laterally affected by the isolation region does not suffer the negative effects of the latter, increasing the fill factor value in the radiation sensor of the invention. In other words, it is observed that the isolation region could be limited to isolating therebetween only the region of the diode where the charge multiplication occurs and not the underlying substrate, avoiding its influxes thereon.

Moreover, still advantageously, such an isolation region, which in fact forms a trench, does not affect both surfaces, but only the front surface. This is particularly advantageous in the case of sensors which are intended to be illuminated on the rear surface since the latter is continuous and unaffected and thus there are no elements which can influence the correct incidence of the radiation, or in any case reduce the sensitive surface thereof.

Further, there are no discontinuities on the rear surface which could adversely affect the generation of additional surface layers or the placement of additional elements such as microlenses or other.

Still advantageously, at the same volume of the photon collection area, the sensor of the invention has a much smaller high electric field region and thus the noise generated in this region, which typically forms a significant part of the dark noise of the sensor, is reduced.

According to another aspect of the invention, at least one passivation layer is interposed between a lateral wall portion of the first isolation region and the substrate at least from the second depth of the third layer towards the rear surface of the substrate. In particular, the layer is not emptied because it contains a sufficiently high concentration of majority carriers of the same type as those of the substrate during the normal operation of the device.

Advantageously, therefore, there is the passivation of at least one lateral portion of the isolation region starting from the third layer towards the bottom of the substrate avoiding the generation of electromagnetic fields which could hinder or otherwise negatively affect the collection of charges by deviating them from the optimal path which crosses the high electric field region. This is particularly advantageous where the isolation region is deeper than the charge multiplication diode.

Still advantageously, the passivation layer prevents it from being injected in the collection area of the charged device generated at the interface between the first isolation region and the substrate.

Still advantageously, if the passivation layer is polarized by means of an electrical contact, it can contribute to the ability to focus the charges generated by the radiation incident to the substrate towards the high electric field region. Furthermore, it is still advantageously observed that if the isolation region is particularly deep in the substrate with respect to the third layer, the contribution of its lateral passivation to the conveying action of the aforesaid charges is undoubtedly significant.

### BRIEF DESCRIPTION OF THE DRAWINGS

Further features and advantages of the invention will become more evident in light of the detailed description of a preferred but non-exclusive embodiment of an optical sensor according to the invention, illustrated by way of non-limiting example with the aid of the accompanying drawings, in which:

FIG. 1 depicts a radiation sensor according to the state of the art in schematic view;

FIG. 2 depicts a radiation sensor according to the invention in schematic view;

FIGS. 3 to 5 depict some embodiment variants of the radiation sensor of FIG. 2.

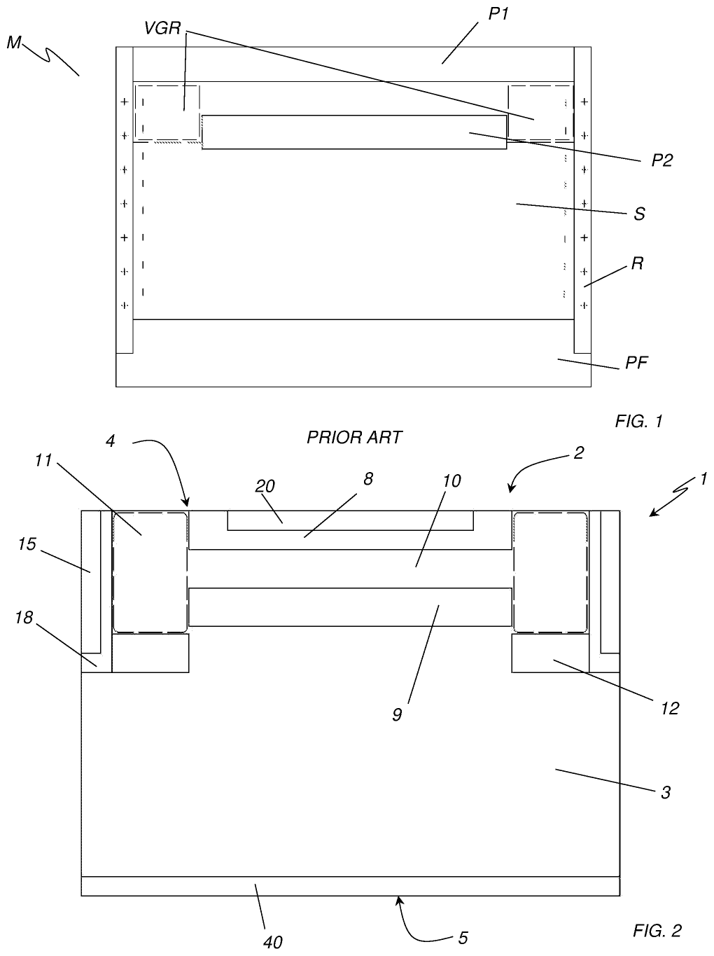

### DETAILED DESCRIPTION OF AN EXEMPLARY PREFERRED EMBODIMENT

With reference to the cited figures, and in particular to FIG. 2, a radiation sensor 1 is described having one or more charge multiplication diodes 2 which will typically, but not necessarily, be polarized so as to work in geiger mode. For ease of description, the sensor 1 depicted in the figures comprises a single diode 2, but it is evident that such an aspect must not be considered limiting for the present invention.

More in detail, the charge multiplication diodes 2 are typically of the avalanche type due to the impact ionization mechanism.

Therefore, the sensor 1 comprises a substrate 3 made of semiconductor material and having two surfaces, a front surface 4 and a rear surface 5 opposite the front surface 4.

On the front surface 4 there is a first layer 8 of semiconductor material doped with a first type of doping. In the figures, such a doping is of type n, but also this aspect must not be considered limiting for the present invention. In fact, the reversal of the types of doping cited in the present description does not make any difference for the purposes of the present patent.

The thickness of the first layer 8 can also be any in accordance with the design parameters of the sensor 1. In general, it is specified that regardless of what can be deduced from the figures, the thicknesses of all the layers indicated in the present patent will be in accordance with the design parameters of the radiation sensor without any limitations for the invention.

The position of the first layer 8 on the front surface of the substrate 3 is also a feature to be considered non-limiting for the invention, since there are embodiment variants not depicted here where the same first layer is made deep in the substrate (although near the front surface) and connected with the front surface by an electrical contact.

The first layer 8 is made to cover a first central area of the front surface 4 of the substrate 3.

There is also a second layer 9 of semiconductor material doped with a doping of a second type of electrically opposite sign to the first type. Typically, also the substrate 3 is doped with a doping of the second type, but with a lower doping level with respect to that of the second layer. Similarly typically, on the rear surface 5 of the substrate there is a further layer 40 doped with the second type of doping, generally at higher doping with respect to that of the substrate. Although it is observed in the figure that such a further doped layer 40 covers the entire rear surface 5, such an aspect must not be considered limiting for different embodiments of the invention where the further doped layer covers only a portion of the rear surface of the substrate.

The second layer 9 is made at a first depth in the substrate 3 and extends substantially parallel to the first layer 8 so as to affect a second area. Furthermore, between the second layer 9 and the first layer 8, a high electric field region 10 for generating the charge multiplication is detectable in the presence of an appropriate polarization of the sensor 1.

Peripherally to the first 8 and the second layer 9 there is a separation space from the edge of the cell which performs a similar function, substantially, a virtual guard ring 11, i.e., it has the function of preventing high electric fields at the edges of the active area.

According to an aspect of the invention, the optical sensor 1 also comprises a third layer 12 of semiconductor material doped with a doping of the second type (thus coinciding with the doping of the second layer 9) and made at a second depth in the substrate 3 greater than the first depth, i.e., it is at a greater depth in the substrate 3 with respect to the depth of the second layer 9. In particular, the third layer 12 affects a third area which, in plan projection, is lateral to the second area.

In other words, as also mentioned above, the third layer 12 substantially forms a frame for the charge multiplication diode 2. In this sense, advantageously, it prevents the charges generated in the substrate 3 from heading towards the virtual guard ring 11, focusing them towards the high electric field region 10 where the multiplication by impact ionization occurs.

Previously, a substantial funnel effect was mentioned since it coarsely, but effectively, exemplifies the function of conveying the charges generated in the substrate 3 by the incidence of the radiation towards the high electric field region 10 where the charge multiplication effect is obtained.

Advantageously, due to such conveying, which is similar to an efficient focusing mechanism of the charges, the size of at least the second layer 9 and the high electric field layer 10, if not also of the first layer 8, can be reduced, obtaining the following advantages:
there is potentially more space for the virtual guard ring 11. This is important in general, but is fundamental for the small size of the cells, in which the minimum size required for the virtual guard ring 11 to be effective would otherwise use the entire width of the cell, without leaving room for the first layer 8 and the second layer 9;
reduced capacity of the diode 2, which allows to construct microcells with faster charging times, in particular in the case of the passive charge multiplication quenching mechanism, obtained through the so-called “quenching resistance”, which is normally used in analogue SiPMs;
a lower cathode capacity also corresponds to a lower gain deriving from the charge multiplication effect, defined as the average number of charges passing through the high electric field layer 10 for each detected photon. An overall lower gain allows less related noise.

However, the focusing effect carried out by the third layer of semiconductor material 12 also allows the use of further constructive expedients.

According to another aspect of the invention, the radiation sensor 1 comprises a first isolation region 15 made peripherally to the substrate 3 and extending deep in the same substrate 3 starting from the front surface 4 up to an intermediate area between it and the rear surface 5. In particular, the figure shows that such a first isolation region 15 is arranged laterally at least at the first 8, the second 9 and the third layer 12. However, such an aspect should not be considered limiting for different embodiments of the invention where, for example, the isolation region only flanks the first two layers, or is deeper than the third layer. Further embodiment variants, however, will be discussed later.

Typically, the isolation region 15 is made by etching the substrate 3 and inserting in the groove thus obtained one or more materials of which typically, but not necessarily, an isolator (typically oxide of the semiconductor material of which the same substrate 3 is formed), but also such an aspect must not be considered limiting for the present invention, the material being can be any and the isolation region can be obtained in different ways with respect to that described. Remaining to the case just described, typically, but not necessarily, the semiconductor material is silicon and the oxide is thus silicon.

In any case, the function of the isolation region 15 is of functional isolation at least between the surface portions of neighbouring cells forming the sensor 1. Since, as mentioned, the isolation region 15 could generate electric or electromagnetic fields which could hinder or otherwise negatively affect the collection of charges which are then directed towards the high electric field region 10, the substrate portion 3 not affected laterally by the isolation region 15 does not suffer such possible negative effects, increasing the fill factor value in the radiation sensor 1 of the invention.

Moreover, still advantageously, such an isolation region 15, which in fact forms a trench, does not affect both surfaces, but only the front surface 4. This is particularly advantageous in the case of radiation sensors 1 which are intended to be illuminated on the rear surface 5 since the latter is continuous and not affected and thus there are no elements which can influence the incidence of the photons.

Still, as mentioned, there are no discontinuities on the rear surface which could negatively affect the generation of additional surface layers or the positioning of additional elements such as lenses or other.

According to another aspect of the invention, a passivation layer 18 is interposed between a lateral wall portion of the first isolation region 15 and the substrate 3, starting from the second depth relative to the third layer 12.

According to some embodiments of the invention, the passivation layer consists of a layer of semiconductor material doped with a doping of the second type. According to other embodiments of the invention, the passivation layer is formed by inducing an appropriate charge in the substrate portion adjacent to the first isolation region by appropriately polarizing the portion of interest of the latter. It follows that the manner in which the aforesaid passivation layer is made is not a limiting feature for the present invention.

In any case, it is observed in the figures that the passivation layer 18 is interposed between the entire first isolation region 15 and the substrate 3, but such an aspect must not be considered limiting for the invention.

Advantageously, therefore, the aforesaid lateral wall portion of the isolation region 15 is passivated at the edges reducing the injection of thermally generated carriers at the interface between the substrate 3 and the first isolation region 15. In other words, the dark current of sensor 1 is reduced. Moreover, with the same passivation, the generation of electromagnetic fields which disturb the collection of charges from the substrate 3 is avoided.

In the figure it is further observed that the third area affected by the third layer 12 on a first side is in contact with the passivation layer 18, while on the opposite side it extends for a length substantially coinciding with the distance between the second layer 9 and the passivation layer 18.

Advantageously, since the third layer 12 and the passivation layer 18 have polarities of the same type, their electrical contact allows, if deemed necessary, to power them jointly, for example by means of an electrical contact connected to the passivation layer 18. Therefore, such a single power supply will increase the ability to focus the charges generated by the photons incident on the substrate 3 towards the high electric field region 10.

Obviously, such features must not be considered limiting for the invention. In fact, it is not necessary that the third layer and the passivation layer are both supplied or are supplied together, just as it is not necessary that they are in contact with one another. Also the fact that the third layer on the opposite side extends for a length substantially coinciding with the distance between the second layer and the passivation layer is not a feature to be considered limiting for the invention, the extension of the third layer can be greater so that, in plan projection, the third layer and second layer partially overlap.

Moreover, in the figures it is observed that the third layer 12 extends parallel to the surface of the sensor 1, but also such an aspect must not be considered limiting for the present invention, the third layer can have a substantially oblique extension or any other.

However, it is still advantageously observed that if the isolation region 15 is deeper in the substrate 3 of the third layer 12, the passivation layer 18 actively collaborates in the conveying action of the aforesaid charges carried out by the third layer 12.

If the passivation layer 18 is appropriately polarized in accordance with the third layer 12, such a contribution will also be advantageously increased.

It is also noted, still advantageously, that if the isolation region 15 is particularly deep in the substrate 3 with respect to the third layer 12, the contribution of the passivation layer 18 to the conveying action of the aforesaid charges is certainly relevant.

Such a collaboration with the third layer 12 is not limited to what has just been said. In fact, in the absence of the passivation layer 18, the isolation region 15 could disturb the collection of charges in the substrate 3 with undesired electric fields.

In the figure it is observed that the first layer 8 of semiconductor material is not unique. In fact, there is a fourth layer 20 of semiconductor material doped with a doping always of the first type and made on the front surface 4 of the substrate 3 above the first layer 8. In particular, the doping of the fourth layer 20 is greater than the doping of the first layer 8. Thereby, substantially, the first layer 8 is patterned, i.e., it has a doping graduality which allows, advantageously, to model the electric fields which involve it especially at the edges. Moreover, different doping species can be used in the fourth layer 20 and in the first layer 8 in order to further model the doping gradient. In any case, this increases the effect of the virtual guard ring 11. Potentially, therefore, such a virtual guard ring 11 could be reduced in extension.

The latter aspect is indeed relevant for the efficiency of the radiation sensors 1. In the case described above, in fact, the distance between the perimeter of the first area and the passivation layer 18 (i.e., between the first layer 8 and the passivation layer 18) is predefined, as is the distance between the second area (and thus the second layer 9) and the same passivation layer 18. However, according to an embodiment variant not shown here, the first area is in contact with the isolation region substantially covering the entire front surface of the substrate. In such a case it is evident that the passivation layer covers the isolation region only from a predetermined depth.

The position of the fourth layer 20 on the front surface of the substrate 3 is also a feature to be considered non-limiting for the invention, since there are embodiment variants not depicted here where the same fourth layer is made deep in the substrate (although near the front surface and in any case at least partially interposed between the front surface and the first layer) and connected with the front surface by an electrical contact. In other embodiment variants, however, the same fourth layer is shaped and comprises the aforesaid electrical contact.

Previously it was said that one of the advantages of the present invention is that the isolation region 15 does not affect the rear surface 5 of the substrate 3. However, in certain situations it may be necessary for there to be an isolation which totally affects the conjunction between adjacent diode 2 substrates 3.

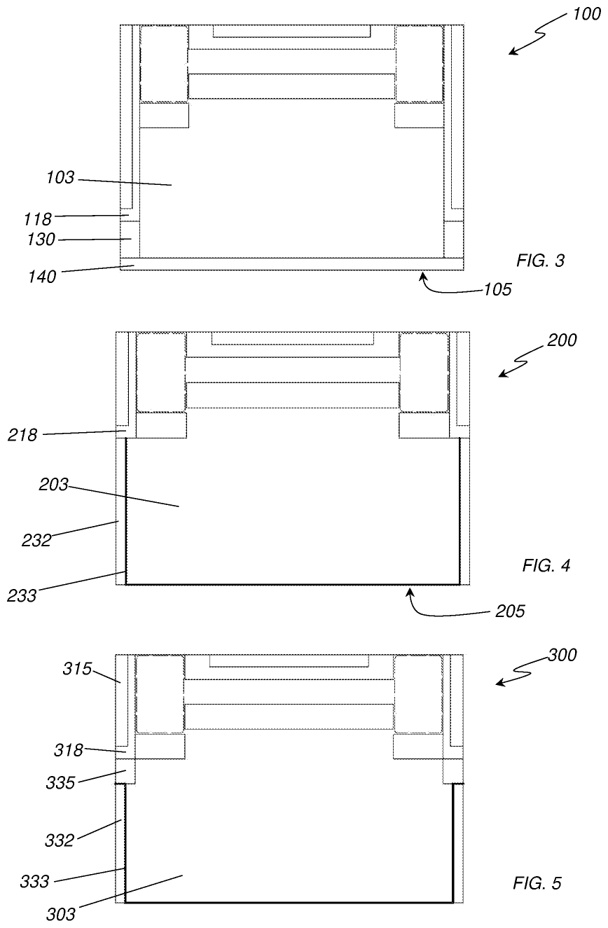

According to an embodiment variant, depicted in FIG. 3, the sensor 100 also comprises a fifth layer 130 of semiconductor material doped with a doping of the second type and interposed between the passivation layer 118 and the rear surface 105 of the substrate 103. Such a fifth layer 130 advantageously allows to increase the functional isolation between adjacent cells of the sensor 100.

Moreover, the fifth layer 130 is in contact with the rear surface 105 which typically has the further doped layer 140 of the same type. Such a further layer 140, which in the backlit sensors 100 covers the photon inlet window, must be powered. Advantageously, such a power supply can be via the fifth layer 130 and the passivation layer 118 and, therefore, with electrical contact placed on the front surface of the sensor 100. This allows to avoid any metallization on the back of the sensor 100.

Such isolation, however, could be considered insufficient especially at the optical level so that, according to a further embodiment variant, depicted in FIG. 4, the radiation sensor 200 comprises a second isolation region 232 made peripherally to the substrate 203 and which extends deep from the rear surface 205. Advantageously, therefore, the functional isolation between adjacent cells can be appropriately calibrated.

Also in this case, and with the same advantages as the passivation layer 218, there is then a sixth layer 233 of doped semiconductor material with a doping of the second type and having thickness in accordance with the design parameters, which is interposed between the second isolation region 232 and the substrate 203. Also such an aspect, however, must not be considered limiting for the present invention, the sixth layer can be absent in different embodiment variants.

The depth of the second isolation region 232 is also not a limiting feature for the present invention. In other words, it is not indispensable for the second isolation region 232 to come into contact with the passivation layer 218. First, in fact, according to different embodiment variants not depicted herein, the second isolation region contacts the first isolation region just as the sixth layer contacts the passivation layer.

According to a further embodiment variant, depicted in FIG. 5, the first isolation region 315 and the second isolation region 332 remain spaced apart as do the passivation layer 318 and the sixth layer 333. A seventh layer 335 of doped semiconductor material with a doping of the second type is interposed therebetween so as to ensure a functional isolation between adjacent cells.

In light of the foregoing, it is understood that the radiation sensor of the invention achieves all the preset objects.

In particular, it has improved performance with respect to equivalent sensors since the fill factor of the microcells has improved.

More in detail, the isolation regions have a lower incidence on the substrate, decreasing, if not substantially cancelling, their contribution to the generation of the so-called dead edge by virtue of the presence of special doping layers covering them.

The third layer and the passivation layer allow to improve the conveying of the electric charges generated in the substrate towards the high electric field layer and effectively triggering the charge multiplication effect.

The invention might be subject to many changes and variants, which are all included in the appended claims. Moreover, all the details may furthermore be replaced by other technically equivalent elements, and the materials may be different depending on the needs, without departing from the protection scope of the invention defined by the appended claims.

The invention claimed is:

1. A diode radiation sensor having one or more charge multiplication diodes (2), said diode radiation sensor (1; 100; 200; 300) comprising:
a substrate (3; 103; 203; 303) made of a semiconductor material, the substrate having a front surface (4) and a rear surface (5; 105; 205) opposite said front surface (4);
a first layer of the semiconductor material (8) doped with a doping of a first type and provided at least adjacently to said front surface (4) of said substrate (3; 103; 203; 303) so as to cover at least a first central area of said front surface (4) of said substrate (3; 103; 203; 303);
a second layer of the semiconductor material (9) doped with a doping of a second type of electrically opposite sign to said first type and provided at a first depth in said substrate (3; 103; 203; 303), said second layer (9) being parallel to said first layer (8) so that a second area, between said first layer (8) and said second layer (9), generates, with a polarization of said diode radiation sensor (1; 100; 200; 300), a high electric field region (10) for generating a charge multiplication effect;
a third layer of the semiconductor material (12) doped with the doping of said second type and provided at a second depth in said substrate (3; 103; 203; 303) greater than said first depth, said third layer (12) defining a third area which, in plan projection, is lateral and at most partially overlapping said second area;
a first isolation region (15; 315) provided peripherally to said substrate (3; 103; 203; 303), the first isolation region extending into said substrate (3; 103; 203; 303) from said front surface (4) to an intermediate area between said front surface (4) and said rear surface (5; 105; 205) so as to be arranged laterally at least to said first (8) and second (9) layers; and
a passivation layer (18; 118; 218; 318) interposed between at least a lateral wall portion of said first isolation region (8) and said substrate (3; 103; 203; 303) at least from said second depth of said third layer (12) towards said rear surface (5; 105; 205).

2. The diode radiation sensor according to claim 1, further comprising a fourth layer of the semiconductor material (20) doped with the doping of said first type and made at least adjacently to said front surface (4) of said substrate (3; 103; 203; 303) above said first layer (8), said doping of said fourth layer (20) being greater than said doping of said first layer (8) so as to obtain a conductivity of said fourth layer (20) greater than the conductivity of said first layer (8).

3. The diode radiation sensor according to claim 1, wherein each point of a perimeter of said second area is spaced from said passivation layer (18; 118; 218; 318) by at least one predetermined distance.

4. The diode radiation sensor according to claim 3, wherein said third area defined by said third layer (12) on a first side is in contact with said passivation layer (18; 118; 218; 318) and extends in an opposite direction for a length at least coincident with said predetermined distance.

5. The diode radiation sensor according to claim 1, further comprising a fifth layer of the semiconductor material (130) doped with the doping of said second type and interposed between said passivation layer (118) and said rear surface (105) of said substrate (103).

6. The diode radiation sensor according to claim 1, further comprising a second isolation region (232; 332) provided peripherally to said substrate (203; 303) and extending in depth into said substrate (203; 303) starting from said rear surface (205).

7. The diode radiation sensor according to claim 6, further comprising a sixth layer of the semiconductor material (233; 333) doped with the doping of said second type, said sixth layer (233; 333) being interposed between said second isolation region (232; 332) and said substrate (203; 303).

8. The diode radiation sensor according to claim 7, further comprising a seventh layer of the semiconductor material (335) doped with the doping of said second type and interposed between said passivation layer (318) and said sixth layer (333).

9. The diode radiation sensor according to claim 6, wherein said first and said second isolation regions (15; 232; 332) are made of an oxide of said semiconductor material.

10. The diode radiation sensor according to claim 1, further comprising an additional layer (40; 140) doped with the doping of the second type on said rear surface of said substrate.
